(19) United States
(12) Patent Application Publication
(10) Pub. No.: US 2005/0170080 A1
(43) Pub. Date: Aug. 4, 2005

(54) System and method for electroless surface conditioning

(76) Inventors: Bulent M. Basol, Manhattan Beach, CA (US); Gerald Marcyk, Portland, OR (US); Homayoun Talieh, San Jose, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/976,534

(22) Filed: Oct. 28, 2004

Related U.S. Application Data
(60) Provisional application No. 60/515,616, filed on Oct. 29, 2003.

(51) Int. Cl. H05K 3/00; C23C 20/00

(52) U.S. Cl. 427/99.3; 427/99.5

(57) ABSTRACT

A system and method for processing, in a single process tool, a surface of a semiconductor workpiece having a barrier layer and a conductor. The single process tool includes a first planarization module, a second planarization module, and an electroless deposition module. The conductor is planarized in the first planarization module until a portion of the barrier layer is exposed. In the second planarization module, the exposed portion of the barrier layer is removed from the surface. The workpiece is then moved to the electroless plating module, where a cap layer is formed on the planarized conductor.

### REFERENCE TO RELATED APPLICATIONS

This application claims priority to U.S. Provisional Application No. 60/515,616, filed on Oct. 29, 2003.

### FIELD OF THE INVENTION

The present invention generally relates to semiconductor processing technologies and, more particularly, to semiconductor interconnect fabrication processes and systems.

### BACKGROUND OF THE INVENTION

Conventional semiconductor devices generally include a semiconductor substrate, usually a silicon substrate, and a plurality of sequentially formed dielectric interlayers, such as silicon dioxide, and conductive paths or interconnects made of conductive materials. The interconnects are usually formed by filling with a conductive material in trenches etched into the dielectric interlayers. In an integrated circuit, multiple levels of interconnect networks laterally extend with respect to the substrate surface. Interconnects formed in different layers can be electrically connected using vias or contacts. A metallization process can be used to fill such features, i.e., via openings, trenches, pads or contacts with a conductive material.

Copper and copper alloys have recently received considerable attention as interconnect materials because of their superior electromigration and low resistivity characteristics. The preferred method of copper metallization is electroplating. Before the electroplating process, the dielectric layer with the features is first coated with a barrier layer. Typical barrier materials generally include tungsten, tantalum, titanium, their alloys, and their nitrides. Next, a seed layer, which is often a copper layer, is deposited on the barrier layer. The seed layer forms a conductive material base for copper crystal growth during the subsequent copper deposition. The deposition of the seed layer is typically followed by an electroplating of the copper on the dielectric and in the vias and trenches.

The electroplating can be done using, for example, a conventional electrochemical deposition (ECD) or a planar deposition process such as electrochemical mechanical deposition (ECMD). Regardless of the plating process, after the plating, the excess copper and the barrier layer portion on the upper dielectric surface are removed to electrically isolate copper in each individual feature. The excess copper and the barrier layers can be typically removed using chemical mechanical polishing (CMP) or electrochemical mechanical polishing (ECMP) processes. After the removal of the excess copper, the copper in the features is coated with a very thin cap layer to further improve electromigration characteristics of the copper in the features.

CMP and cap deposition steps are typically carried out in system platforms that are separated from each other. Such process environments often cause copper surface contamination or copper surface aging. It is important to minimize contamination and aging of the top copper surfaces to ensure not only the reliability of interconnects but also to prevent problems in subsequent processing steps caused by contamination and aging of the copper surfaces. The skilled artisan will appreciate that it is preferable that CMP of the barrier layer (and any cleaning and annealing steps) be immediately followed by deposition of the cap layer to minimize contamination and aging of the copper surfaces.

### SUMMARY OF THE INVENTION

In accordance with one aspect of the invention, a system for processing a workpiece by applying planarization and electroless deposition is provided. The workpiece includes a surface lined with a barrier layer and a conductor. The system includes a first planarization module, a second planarization module, and an electroless deposition module. The first planarization module is provided for planarizing the conductor until a portion of the barrier layer is exposed. The second planarization module is for removing the portion of the barrier layer from the surface of the workpiece. The electroless deposition module is provided for depositing a cap layer on the planarized conductor. In preferred embodiments, the cap layer is formed of a Co layer, a CoW layer or a Co-alloy layer.

In accordance with another aspect of the invention, a method of processing a surface of a workpiece in a single process tool is provided. The single process tool includes a first planarization module, a second planarization module, and an electroless deposition module. The conductor is planarized in the first planarization module until a portion of the barrier layer on the surface of the workpiece is exposed. After the conductor is planarized in the first planarization module, the workpiece is moved to the second planarization module where the exposed portion of the barrier layer is removed from the surface of the workpiece. After the exposed portion of the barrier layer is removed, the workpiece is moved to the electroless plating module, where electroless plating is applied to the workpiece to form a cap layer on the planarized conductor. In one embodiment, the single process tool may include an anneal module and the workpiece is moved to the anneal module where the cap layer is annealed after the application of electroless plating.

According to yet another aspect of the invention, a system is provided for processing a semiconductor workpiece having a barrier layer and a conductive layer over the barrier layer. The system includes first and second planarization modules and a deposition module. The first planarization module is configured to planarize the conductive layer until a portion of the barrier layer is exposed. The second planarization module is configured to remove the exposed portion of the barrier layer from the workpiece. The deposition module is configured to deposit a cap layer on the conductive layer after removal of the portion of the barrier layer. The system may further include an anneal module configured to anneal the workpiece.

In accordance with yet another aspect of the invention, a system is provided for processing a workpiece by applying planarization and electroless deposition. The workpiece includes a surface lined with a barrier layer and a conductor over the barrier layer. The system includes at least one planarization module within a housing, wherein the at least one planarization module is configured to remove and planarize the conductor and a portion of the barrier layer. The system also includes an electroless deposition module within the housing, wherein the electroless deposition module is configured to deposit a cap layer on the planarized conductor. In an embodiment, the at least one planarization module includes a cleaning chamber configured to clean and rinse the workpiece after the planarization. In another embodiment, the electroless deposition module includes a cleaning chamber configured to clean and rinse the workpiece after the electroless deposition.

### BRIEF DESCRIPTION OF THE DRAWINGS

These and other aspects of the invention will be readily apparent to the skilled artisan in view of the description below, the appended claims, and from the drawings, which are intended to illustrate and not to limit the invention, and wherein:

FIG. 1A is a schematic side view of a substrate on which a copper layer has been electrochemically formed;

FIG. 1B is schematic side view of the substrate shown in FIG. 1A wherein copper layer has been planarized by a first planarization step in accordance with preferred embodiments;

FIG. 1C is a schematic side view of the substrate shown in FIG. 1B wherein planar copper deposits have been electrically isolated by a second planarization step by removing the barrier layer from the upper surface of the substrate;

FIG. 1D is a schematic side view of the substrate shown in FIG. 1C wherein a thin cap layer is deposited on the planar copper deposits by an electroless deposition step; and

FIG. 2 is a schematic top plan view of an embodiment of a system of a present invention to perform an embodiment of the process of the present invention.

### DETAILED DESCRIPTION OF THE PREFERRED EMBODIMENTS

The following detailed description of the preferred embodiments and methods presents a description of certain specific embodiments to assist in understanding the claims. However, one may practice the present invention in a multitude of different embodiments and methods as defined and covered by the claims.

It will be appreciated that the apparatuses may vary as to configuration and as to details of the parts, and that the methods may vary as to the specific steps and sequence, without departing from the basic concepts as disclosed herein. The following patent and patent applications provide more detailed descriptions of electrochemical mechanical deposition (ECMD) and electrochemical mechanical polishing (ECMP) methods, apparatuses, and systems that may be used in accordance with preferred embodiments of the present invention: U.S. patent application Ser. No. 09/795,687, filed Feb. 27, 2001, U.S. patent application Ser. No. 09/841,622, filed Apr. 23, 2001, U.S. patent application Ser. No. 10/041,029, filed Dec. 28, 2001, and U.S. Pat. No. 6,352,623. The entire disclosures of the foregoing patent and patent applications are hereby incorporated herein by reference.

As will be described in more detail below, the present invention provides a method and a system for removing excess conductive material from a substrate and coating the substrate with a conditioning layer. Preferably, the coating is selective to the conductive material, such as by using an electroless deposition process. In an embodiment, the conductive material may be copper and the coating may be a conditioning material layer to further improve electromigration characteristics of the copper.

In a preferred embodiment, the conductor is removed using chemical mechanical polishing (CMP). The skilled artisan will appreciate that other material removal processes can be used, including but not limited to, electropolishing and electrochemical mechanical polishing (ECMP). According to an embodiment, before the removal process, the semiconductor substrate may be electroplated with an electroplating process such as electrochemical deposition (ECD) or electrochemical mechanical deposition (ECMD) within an integrated system. The ECMD process produces a planar layer and descriptions of various ECMD methods and apparatuses can be found in the following patents and pending applications: U.S. Pat. No. 6,176,992, entitled “Method and Apparatus for Electrochemical Mechanical Deposition,” U.S. Pat. No. 6,354,116, entitled “Plating Method and Apparatus that Creates a Differential Between Additive Disposed on a Top Surface and a Cavity Surface of a Workpiece Using an External Influence,” U.S. Pat. No. 6,471,847, entitled “Method for Forming Electrical Contact with a Semiconductor Substrate” and U.S. Pat. No. 6,610,190, entitled “Method and Apparatus for Electrodeposition of Uniform Film with Minimal Edge Exclusion on Substrate,” the entire disclosures of all of which are hereby incorporated herein by reference in their entireties.

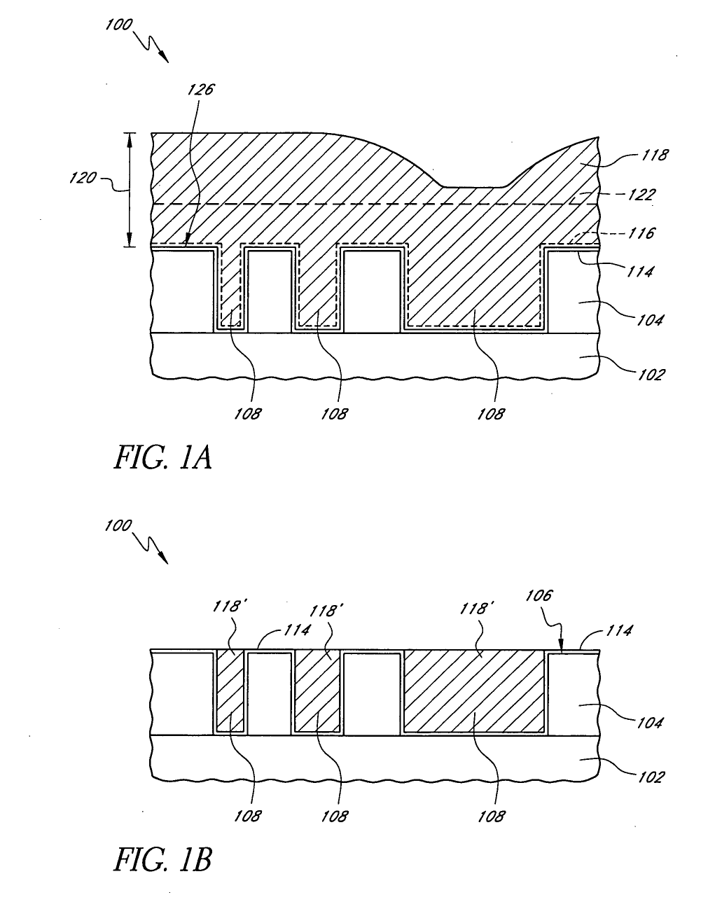

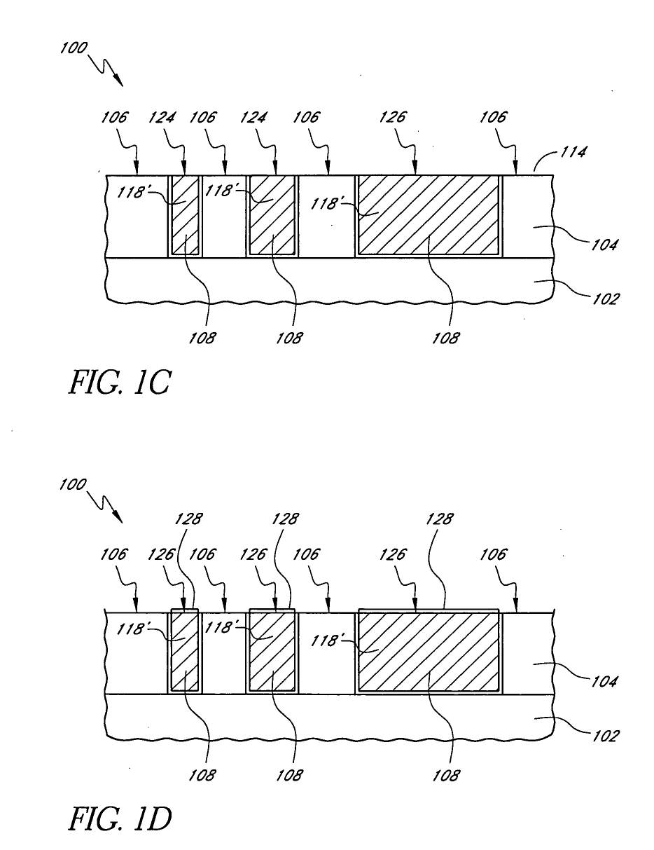

Reference will now be made to the drawings wherein like numerals refer to like parts throughout. A process sequence in accordance with a preferred embodiment will be described below with reference to FIGS. 1A through 1D.

FIG. 1A shows an electrochemically plated substrate 100 exemplifying a portion of a multilayer structure formed over a semiconductor wafer 102, such as a silicon wafer. In an embodiment, the substrate 100 includes a dielectric layer 104 formed on the surface over the wafer 102. As shown in FIG. 1A, the dielectric layer 104 has a top surface 106. Features 108 are preferably formed into the dielectric layer 104. The features 108, as well as the top surface 106 of the dielectric layer 104, are preferably coated with a barrier layer 114 or a glue layer formed of, for example, a tantalum (Ta) and/or tantalum nitride (TaN) layer. The skilled artisan will understand that well-known processes in the art, including, but not limited to, physical vapor deposition. (PVD) and atomic layer deposition (ALD) may be used to deposit the barrier layer 114 or glue layer. While illustrated as exposing a surface of this semiconductor wafer 102, the skilled artisan will appreciate that other structures (e.g., transistors, plugs, capacitors, and interlevel dielectrics) will typically intervene between the copper to be formed and the underlying wafer 102.

Next, a seed layer 116, which is a thin film of conductive material, is preferably deposited on top of the barrier layer 114 to allow for a subsequent copper plating process. The skilled artisan will understand that the seed layer 116 is preferably a thin film of copper, but that other suitable conductive materials may be used for the seed layer and the subsequently deposited layer of conductive material.

For the purpose of simplicity, the seed layer 116 is not shown in the remaining FIGS. (1B-1D) and the subsequent layer of conductive material will be referred to as a copper layer 118, in accordance with a preferred embodiment. In a preferred embodiment, the copper layer 118 is electroplated onto the seed layer 116 to fill the features 108. The deposition of the copper layer 118 results in an excess layer 120, which extends from the seed layer 116 to the top surface of the copper layer 118, as shown in FIG. 1 A.

The thickness of the excess layer 120 depends on the electroplating process used for deposition of the copper layer 118. The electroplating process is preferably performed using either an electrochemical deposition (ECD) process or an electrochemical mechanical deposition process (ECMD). If ECD is the electroplating process, the excess layer 120 is a non-uniform layer having large steps on the large features. If ECMD is the electroplating process, a planar top layer, as shown by dotted line 122 in FIG. 1A, is formed. As can be seen in FIG. 1A, in comparison to the ECMD process, the ECD process produces more excess copper and a non-planar top surface. The excess copper must be removed by a subsequent removal process, which will be described in more detail below. The skilled artisan will appreciate that it is preferable to have a thinner and planar excess layer 120.

According to this embodiment, a first material removal step is performed to remove the excess layer 120 after the deposition of the copper layer 118. As shown in FIG. 1B, at the first material removal step, the excess layer 120 is removed down to the barrier layer 114 covering the upper surface 106 of the dielectric 104. Referring to FIG. 1B, after completion of the end of the first material step, or the copper removal step in the illustrated embodiment, the remaining copper deposits 118′ are confined into the features 108. The first material removal step results in copper deposits 118′ that are physically isolated from one another, as shown in FIG. 1B. The skilled artisan will appreciate that the first material removal step can be carried out using, for example, a CMP process.

After the first material removal step, at a second material removal step, or a barrier removal step in the illustrated embodiment,, portions of the barrier layer 114 that cover the upper or top surface 106 of the dielectric layer 104 are removed. The removal of these portions of the barrier layer 114 exposes the surface 106 of the dielectric layer 104, as illustrated in FIG. 1C. As shown in FIG. 1C, the second material removal step electrically isolates the copper deposits 118′ from one another and from top surface 106 of the dielectric layer 104. The top surfaces 126 of the copper deposits 118′ are separated from one another by the top surface 106 of the dielectric layer 104, as shown in FIG. 1C. As in the case of the first material removal step, the second material removal step preferably also uses CMP to remove the barrier layer 114. After the second material removal step, a first cleaning step is preferably carried out to clean the CMP chemicals off the substrate 100, to passivate, rinse, and dry the substrate 100 and the copper deposits 118′. Following the first cleaning step, the substrate 100 may be annealed in a first anneal step.

As shown in FIG. 1D, following the removal of the barrier layer 114 (and first cleaning step and/or first anneal step, if any), a deposition step is carried out to coat top copper surfaces 126 with a cap layer 128. Preferably, the deposition selectively coats the top copper surfaces 126, and in the illustrated embodiment comprises electroless deposition. The cap layer 128 may be a thin layer of cobalt (Co) or Co alloys, such as CoWP type of alloys formed from an electroless plating solution containing Co. In a preferred embodiment, the thickness of the cap layer 128 is preferably in the range of about 5-50 Angstroms, and more preferably in the range of about 10-20 Angstroms.

After the electroless deposition step, the substrate 100 is preferably cleaned in a second cleaning step, which may include rinsing and drying. A second anneal step may follow the second cleaning step to anneal the cap layer 128 deposited on the substrate 100. Although the anneal steps may be applied after both the barrier layer 114 removal and the electroless deposition of the cap layer 128, the skilled artisan will understand that anneal steps are not necessary after both the barrier layer 114 removal and the electroless deposition steps. For example, an anneal step may be performed after either the barrier layer 114 removal step or the electroless deposition step. Alternatively, anneal steps are not performed at all, depending on the desired crystal structure of the selected conductive materials.

As mentioned in the Background of the Invention Section, in the prior art, CMP and cap deposition steps are typically carried out in system platforms that are separated from each other. A preferred embodiment of the present invention integrates these two processes on the same platform, thereby eliminating the danger of copper surface contamination or copper surface aging. It is important to minimize contamination and aging of the top copper surfaces 126 to ensure not only the reliability of interconnects but also to prevent problems in subsequent processing steps caused by copper surface contamination and aging. The skilled artisan will appreciate that it is preferable that CMP of the barrier layer 114 (and any cleaning and annealing steps) be immediately followed by deposition of the cap layer 128 to minimize contamination and aging of the copper surfaces 126.

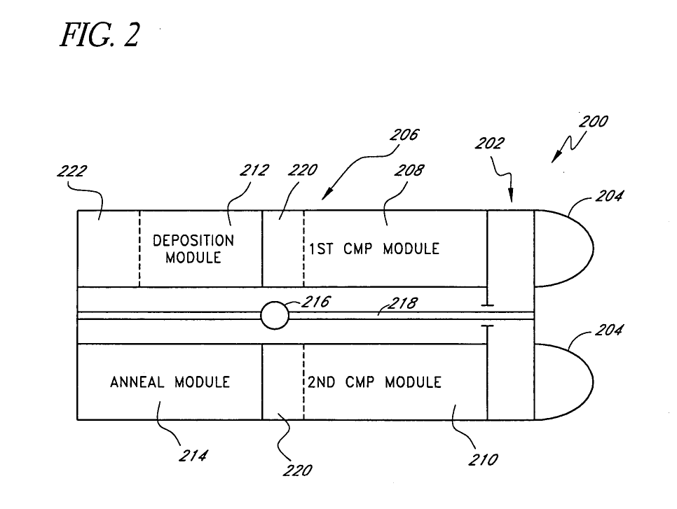

An example of an integrated system 200 that can be used to practice an embodiment of the present invention is schematically shown in FIG. 2. As shown in FIG. 2, the system 200 is a single process tool that includes CMP and cap deposition modules on the same platform. The system 200 may have a load/unload section 202 for loading and unloading wafer cassettes or boxes 204 and a process section 206 for processing wafers. The skilled artisan will appreciate that the load/unload section 202 may comprise a shared load/unload platform for the wafer boxes 204.

Wafers from the boxes 204 may be delivered to the process section 206 using one or more robots 216, which may be located either in the process section 206 or in the load/unload section 202, or in both sections. In a preferred embodiment shown in FIG. 2, the process section 206 has a first CMP module 208, a second CMU module 210, a deposition module 212 and an anneal module 214. In another embodiment, one or both of the CMP modules 208, 210 may also be replaced with Electrochemical Mechanical Polishing (ECMP) modules. An ECMP process can be performed in an ECMP module by reversing the polarities and using either a plating solution or an electroetching solution. Descriptions of ECMP modules and processes can be found in U.S. patent application Ser. No. 09/841,622, entitled Electroetching System and Method, filed Apr. 23, 2001, and U.S. patent application Ser. No. 10/391,924, entitled Electroetching System and Process, filed Mar. 18, 2003, the entire disclosures of both of which are hereby incorporated herein by reference in their entireties.

Each CMP module 208, 210 may have integrated cleaning chambers 220 within them. Therefore, the first and second material removal steps and the first cleaning step can all be performed in the CMP modules 208, 210. Such CMP modules are disclosed described in more detail in U.S. patent application Ser. No. 10/369,118, entitled Integrated System for Processing Semiconductor Wafers, filed Feb. 18, 2003, the entire disclosure of which is hereby incorporated herein by reference.

The electroless deposition module 212 may also have an integrated cleaning chamber 222. The skilled artisan will understand that the cleaning chamber may be a separate chamber in the system 200 or the cleaning chamber 222 may be an integral part of the electroless deposition module 212 (as in the illustrated embodiment). An integrally connected electroless deposition module 212 and cleaning chamber 220 may be vertically configured. One such vertically configured plating and cleaning chamber system is described in U.S. patent application Ser. No. 10/041,029, entitled Vertically Configured Chamber Used for Multiple Processes filed Dec. 28, 2001, the entire disclosure of which is hereby incorporated herein by reference.

In a preferred embodiment, the modules 208, 210, 212 of the system 200 are all within a common housing such that the substrate 100 is not exposed to the atmosphere when it is transported between modules, thereby eliminating the danger of copper surface contamination or copper surface aging, as there is a higher purity level behind the load/unload section 202 relative to the clean room atmosphere. The skilled artisan will understand that the system 200 may be a cluster tool.

Accordingly, referring to FIGS. 1A, 1B, 1C, and 2, in an embodiment, the substrate 100 is first delivered from a wafer box 204 to the first CMP module 208 of the system 200 for the first material removal step to remove the excess conductive layer 120. The skilled artisan will understand that a robot 216 may be used to transport the substrate 100 from a wafer box 204 through the load/unload section 202 to the first CMP module 208. As discussed above, CMP may be used to remove the excess layer 120 down to the barrier layer 114.

After the removal of the excess layer 120, the substrate 100 is preferably taken to the second CMP module 210 for the second material removal step to remove portions of the barrier layer 114 from the surface 106 of the dielectric layer 104. After the second material removal step, the substrate 100 may go through the first cleaning step in the second CMP module 210. After the first cleaning step, the substrate 100 may be taken to the anneal module 214 for the first anneal step.

Referring to FIGS. 1D and 2, following the second material removal step (and first cleaning and/or first anneal step, if any), the substrate 100 is delivered to the deposition module 212 for selective, and preferably electroless, deposition of the cap layer 128 on the top surface 126 of the copper deposits 118′ in the features 108. Following the electroless deposition of the cap layer 128, the substrate 100 may be cleaned in the second cleaning step. After the second cleaning step, the substrate 100 may be annealed at the second anneal step. Once the annealing is complete, the substrate 100 is taken back to wafer box 204 through the load/unload section 202.

The skilled artisan will appreciate that the substrate 100 may be transported through the system 200 by one or more robots 216. For example, in the illustrated embodiment, a shared robot 216 is capable of moving the substrate 100 around the system between either of the modules 208, 210 and the wafer boxes 204. In the illustrated embodiment of FIG. 4, the robot 216 may slide along a track 218 to move around within the system 200. In the illustrated embodiment, the same robot 216 serves all of the planarization, deposition, and anneal modules. In alternative embodiments, the system 200 may have more than one robot 216, each situated in a different location to access different modules and wafer boxes. It will be appreciated that the removal or planarization steps of the copper and barrier layers may be performed in one or more modules of the system. The modules can be ECMP or CMP modules. For example, in one approach, the bulk of the excess copper may be removed in a first module, and the remaining copper and the barrier layers may be removed in a second module. Although in the above embodiments, the system includes two planarization modules, in an alternative embodiment, a system may include three or more modules. In such a multiple module system in a first planarization module, the bulk of the excess copper is removed; in a second module, the remaining excess copper is removed; and in a third module, the barrier layer is removed.

Although various preferred embodiments have been described in detail above, those skilled in the art will readily appreciate that the present invention extends beyond the specifically disclosed embodiments to other alternative embodiments and/or uses of the invention and obvious modification thereof without materially departing from the novel teachings and advantages of this invention. Thus, it is intended that the scope of the present invention herein disclosed should not be limited by the particular disclosed embodiments described above, but should be determined only by a fair reading of the claims that follow.

1. A system for processing a workpiece by applying planarization and electroless deposition, the workpiece including a surface lined with a barrier layer and a conductor over the barrier layer, comprising:
a first planarization module within a housing, the first planarization module configured to planarize the conductor until a portion of the barrier layer on the surface of the workpiece is exposed;
a second planarization module within the housing, the second planarization module configured to remove the portion of the barrier layer from the surface of the workpiece; and
an electroless deposition module within the housing, the electroless deposition module configured to deposit a cap layer on the planarized conductor after removal of the portion of the barrier layer.

2. The system of claim 1, further comprising an anneal module within the housing, the anneal module configured to anneal the workpiece prior to depositing the cap layer in the electroless deposition chamber.

3. The system of claim 1, further comprising an anneal module within the housing, the anneal module configured to anneal the workpiece subsequent to depositing the cap layer in the electroless deposition chamber.

4. The system of claim 1, wherein the first planarization module includes a cleaning chamber configured to clean the workpiece after planarizing.

5. The system of claim 1, wherein the second planarization module includes a cleaning chamber configured to clean the workpiece after removing the portion of the barrier layer.

6. The system of claim 1, wherein the first and second planarization modules are chemical mechanical polishing modules.

7. The system of claim 1, wherein at least one of the first and second planarization modules is an electrochemical mechanical polishing module.

8. The system of claim 1, wherein the workpiece is a semiconductor wafer.

9. The system of claim 1, wherein the first planarization module is configured to planarize the conductor, wherein the conductor is copper.

10. The system of claim 1, wherein the electroless deposition module contains electroless plating solution containing Co and the cap layer is a Co layer, a CoW layer or a Co-alloy layer.

11. The system of claim 1, wherein the cap layer has a thickness of about 5-50 Angstroms.

12. A method of processing a surface of a workpiece in a single process tool including a first planarization module, a second planarization module, and a selective deposition module, the workpiece including a surface lined with a barrier layer and conductor over the barrier layer, comprising:
planarizing the conductor in the first planarization module until a portion of the barrier layer on the surface is exposed;
moving the workpiece to the second planarization module;
removing, in the second planarization module, the portion of the barrier layer from the surface;
moving the workpiece to the selective plating module after removing the portion of the barrier layer; and
applying selective plating, in the selective plating module, to form a cap layer on the planarized conductor.

13. The method of claim 12, further comprising:
moving the workpiece to an anneal module within the single process tool after applying electroless plating; and
annealing the cap layer and the planarized conductor in the anneal module.

14. The method of claim 12, further comprising:
moving the workpiece to an anneal module within the single process tool prior to applying selective plating; and
annealing the planarized conductor in the anneal module.

15. The method of claim 12, further comprising cleaning the workpiece after planarizing the conductor in the first planarization module.

16. The method of claim 12, further comprising cleaning the workpiece after planarizing the conductor in the second planarization module.

17. The method of claim 12, further comprising cleaning the workpiece after applying the selective plating in the selective plating module.

18. The method of claim 12, wherein the cap layer has a thickness of about 5-50 Angstroms.

19. A cluster tool for processing a semiconductor workpiece having a barrier layer and a conductive layer over the barrier layer, the cluster tool comprising:
a first planarization module configured to planarize the conductive layer until a portion of the barrier layer is exposed;
a second planarization module configured to remove the exposed portion of the barrier layer from the workpiece; and
a deposition module configured to deposit a cap layer on the conductive layer after removal of the portion of the barrier layer.

20. The cluster tool of claim 19, further comprising an anneal module configured to anneal the workpiece.

21. The cluster tool of claim 19, wherein the deposition module is configured to use an electroless plating solution containing Co to deposit a cap layer formed of a Co layer, a CoW layer, or a Co-alloy layer.

22. The cluster tool of claim 19, further comprising at least one robot configured to transport the workpiece around the cluster tool.

23. The cluster tool of claim 19, wherein the first and second planarization modules each comprise a cleaning chamber configured to clean the workpiece.

24. The cluster tool of claim 19, wherein the deposition chamber comprises a cleaning chamber configured to clean the workpiece.

25. A system for processing a workpiece by applying planarization and electroless deposition, the workpiece including a surface lined with a barrier layer and a conductor over the barrier layer, comprising:
at least one planarization module within a housing, the at least one planarization module configured to remove and planarize the conductor and a portion of the barrier layer; and
an electroless deposition module within the housing, the electroless deposition module configured to deposit a cap layer on the planarized conductor.

26. The system of claim 25, wherein the at least one planarization module includes a cleaning chamber configured to clean and rinse the workpiece after the planarization.

27. The system of claim 25, wherein the electroless deposition module includes a cleaning chamber configured to clean and rinse the workpiece after the electroless deposition.
